(19) United States
(12) Patent Application Publication
(10) Pub. No.: US 2019/0164851 A1
(43) Pub. Date: May 30, 2019

(54) TEST INTERFACE BOARD AND SYSTEM INCLUDING THE SAME

(71) Applicant: SAMSUNG ELECTRONICS CO., LTD., SUWON-SI, (KR)

(72) Inventors: JONGWOON YOO, SEOUL (KR); DAEHA HWANG, CHEONAN-SI (KR); YOUNG-GI MIN, ASAN-SI (KR); SOOYONG PARK, ASAN-SI (KR); JONGKOOK KIM, ASAN-SI (KR)

(21) Appl. No.: 16/047,439

(22) Filed: Jul. 27, 2018

(30) Foreign Application Priority Data
Nov. 30, 2017 (KR) 10-2017-0163364

(51) Int. Cl. H01L 21/66; G01R 1/02; G01R 31/28; G01R 1/04; H01L 23/00; G11C 29/04; G11C 29/56

(52) U.S. Cl. CPC H01L 22/14; G01R 1/025; G01R 31/2834; G01R 1/0466; G11C 2029/5602; H01L 22/34; G11C 29/04; G11C 29/56016; G11C 2029/0403; H01L 24/13

(57) ABSTRACT

A test system includes automatic test equipment configured to test a device under test, and a test interface board configured to measure a second voltage applied to the device under test based on a first voltage supplied from the automatic test equipment. The test interface board includes a sensing wiring configured to transmit the measured second voltage to the automatic test equipment. The second voltage is measured at an interior location of the device under test.

### CROSS-REFERENCE TO RELATED APPLICATIONS

This application claims priority under 35 U.S.C. § 119 to Korean Patent Application No. 10-2017-0163364 filed on Nov. 30, 2017, the disclosure of which is incorporated by reference herein in its entirety.

### TECHNICAL FIELD

Exemplary embodiments of the inventive concept described herein relate to an electronic device, and more particularly, to a test device that tests the electrical characteristic of a semiconductor device.

### DISCUSSION OF THE RELATED ART

As the performance and integration of semiconductor devices increase, the types of semiconductor devices used to implement electronic devices have been diversified. As a result, the design of a test interface board used to connect automatic test equipment (ATE) and a device under test (DUT) is becoming more complicated.

The ATE may input a test pattern to the DUT, may receive an output signal from the DUT in response, and may compare the value corresponding to the received output signal with an expected value to test the DUT.

When the ATE outputs a test pattern, if an accurate driving voltage is not supplied to the DUT, the accuracy of the test operation performed on the DUT may be reduced.

### SUMMARY

Exemplary embodiments of the inventive concept provide a test interface board, and a system that applies an accurate driving voltage to a device under test (DUT), thereby improving the accuracy of the test.

According to an exemplary embodiment of the inventive concept, a test system includes an automatic test equipment configured to test a device under test, and a test interface board configured to measure a second voltage applied to the device under test based on a first voltage supplied from the automatic test equipment. The test interface board includes a sensing wiring configured to transmit the measured second voltage to the automatic test equipment. The second voltage is measured at an interior location of the device under test.

According to an exemplary embodiment of the inventive concept, a test interface board connected to a device under test includes a power plane that receives a first voltage from an automatic test equipment, and a sensing wiring that measures a second voltage applied to the device under test through the power plane. The sensing wiring is connected to an interior location of the device under test.

According to an exemplary embodiment of the inventive concept, a semiconductor device includes a voltage terminal that receives a driving voltage from a test interface board. The semiconductor device is connected to the test interface board, and the test interface board measures an electrical characteristic of the semiconductor device. The semiconductor device further includes a ground terminal that receives a ground voltage from the test interface board, a data terminal that receives data from the test interface board, and a sensing terminal that measures the applied driving voltage. The sensing terminal is disposed on a surface of the semiconductor device, and is connected to a sensing wiring of the test interface board. The sensing wiring is connected to a sensing point disposed at an interior location of the semiconductor device, and the driving voltage is measured at the sensing point.

According to an exemplary embodiment of the inventive concept, a method of manufacturing a semiconductor device includes forming the semiconductor device as part of a wafer or a package, and testing the semiconductor device. The testing of the semiconductor device is performed using an automatic test equipment configured to test the semiconductor device, and a test interface board configured to measure a second voltage applied to the semiconductor device based on a first voltage supplied from the automatic test equipment. The test interface board includes a sensing wiring configured to transmit the measured second voltage to the automatic test equipment. The second voltage is measured at an interior location of the semiconductor device.

### BRIEF DESCRIPTION OF THE DRAWINGS

The above and other features of the inventive concept will become more apparent by describing in detail exemplary embodiments thereof with reference to the accompanying drawings, in which:

FIG. 1 is a perspective view of a test interface board, according to an exemplary embodiment of the inventive concept.

FIG. 2 illustrates a conceptual diagram of a test system, according to an exemplary embodiment of the inventive concept.

FIG. 3 is circuit diagram of a voltage controller, according to an exemplary embodiment of the inventive concept.

FIG. 4 illustrates a conceptual diagram of a test system, according to an exemplary embodiment of the inventive concept.

FIG. 5 illustrates a conceptual diagram of a test system, according to an exemplary embodiment of the inventive concept.

FIG. 6 illustrates a conceptual diagram of a test system, according to an exemplary embodiment of the inventive concept.

FIG. 7 illustrates a conceptual diagram of a test system, according to an exemplary embodiment of the inventive concept.

### DETAILED DESCRIPTION OF THE EXEMPLARY EMBODIMENTS

Exemplary embodiments of the inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an exemplary embodiment may be described as a “second” element in another exemplary embodiment.

As is traditional in the field of the inventive concept, exemplary embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies.

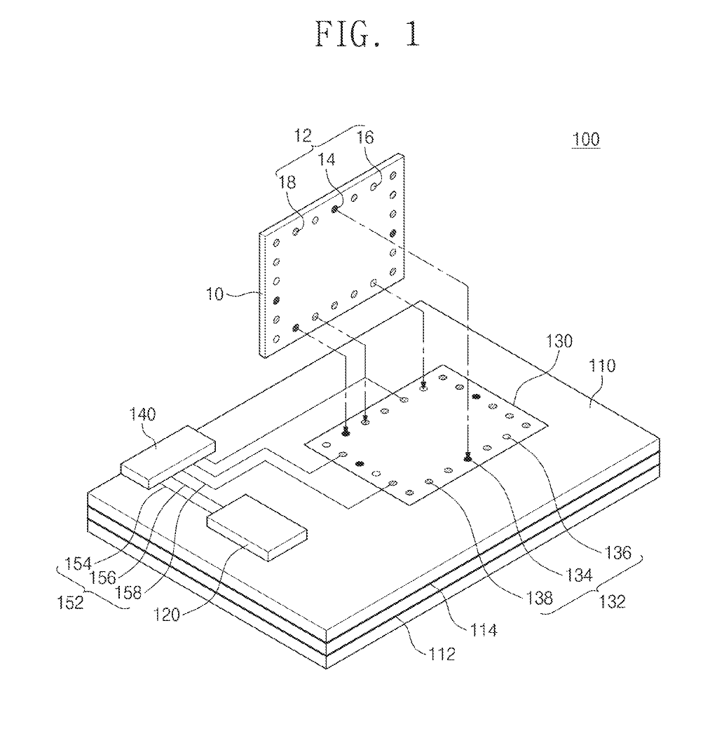

FIG. 1 is a perspective view of a test interface board, according to an exemplary embodiment of the inventive concept.

A test interface board 100 may be used for an interface operation between a device under test (DUT) 10 and automatic test equipment (ATE) to test the DUT 10.

The DUT 10 may be connected to the ATE through the test interface board 100.

In exemplary embodiments, the ATE is a circuit that inputs a test pattern to the DUT 10, receives an output signal from the DUT 10, and compares a value corresponding to the received output signal with an expected value to test the DUT 10. The ATE is described in further detail below.

In exemplary embodiments, the DUT 10 includes a circuit element. The circuit element may be formed, for example, through a semiconductor manufacturing process. In exemplary embodiments, the DUT 10 may include, for example, a volatile memory device. The volatile memory device may include, for example, a static random access memory (SRAM), a dynamic RAM (DRAM), a synchronous DRAM (SDRAM), etc.

In exemplary embodiments, the DUT 10 may include, for example, a nonvolatile memory device. The nonvolatile memory device may include, for example, a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), etc.

The DUT 10 may include, for example, a non-memory device such as a microprocessor, a controller, a logic circuit, etc. The DUT 10 may include, for example, a system semiconductor device in which a logic circuit and a memory circuit are integrated such as, for example, a large scale integration (LSI) device. The DUT 10 may be, for example, an application processor (AP).

In exemplary embodiments, The DUT 10 may be a semiconductor device of a wafer-stage that occurs before a packaging process has been performed. For example, the DUT 10 may be a semiconductor die obtained by dividing a semiconductor wafer, in which a semiconductor circuit is formed, through a dicing process. In this case, the test interface board 100 may be a probe card that tests the semiconductor die, and pads 132 of the test interface board 100 may be in the shape of a needle.

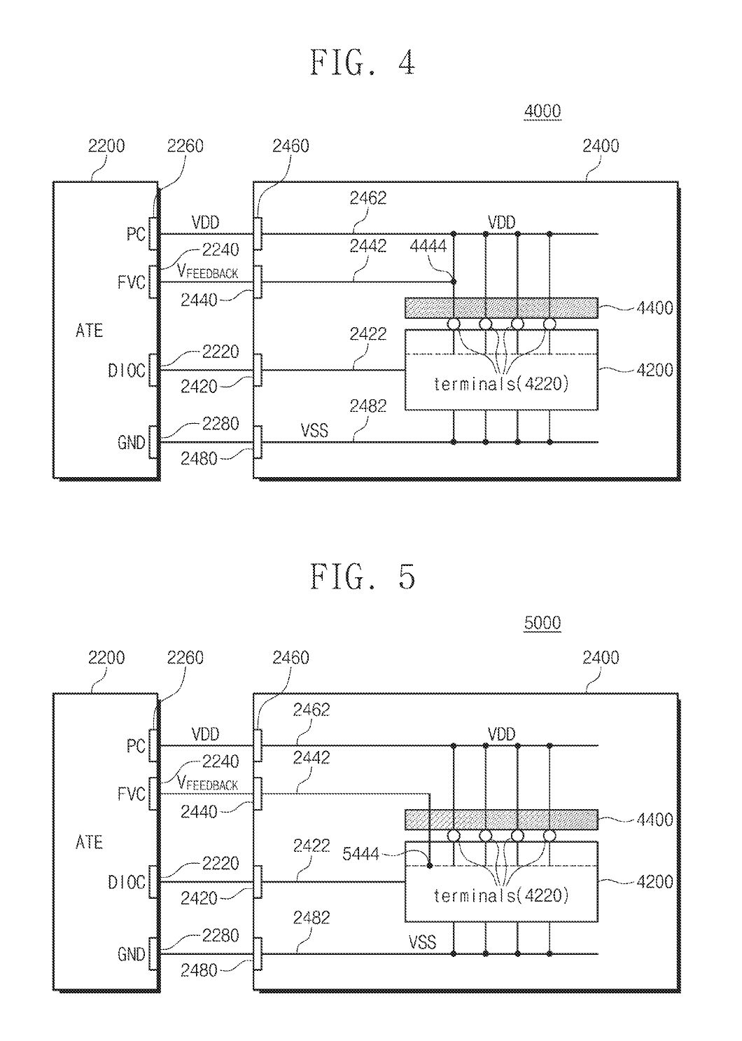

In exemplary embodiments, the DUT 10 may be a semiconductor package in which the semiconductor die is packaged. The DUT 10 may be in the form of an integrated package in which a plurality of homogeneous or heterogeneous semiconductor packages are integrated into one package. For example, the DUT 10 may be a fine ball grid array semiconductor (FBGA). In this case, the test interface board 100 may be a hi-fix board, and the pads 132 of the test interface board 100 may be in the shape of a socket. In addition, in this case, the semiconductor package may be loaded onto a socket, and terminals 12 of the semiconductor package may be electrically connected to the pads 132 of the test interface board 100 through pads included in the socket, respectively. The socket may be a connection medium between the test interface board 100 and the DUT 10. The socket may be an element having a finite lifetime, and the accuracy of the test process performed on the DUT 10 may decrease as the contact resistance of the socket increases. This will be described in further detail with reference to FIG. 4.

In exemplary embodiments, the DUT 10 includes a plurality of the terminals 12 for connecting with the test interface board 100. In exemplary embodiments, the terminals 12 include at least one power terminal 14, at least one ground terminal 16, and at least one data terminal 18. The type and quantity of the terminals 12 may vary depending on a signal received through the terminals 12.

A driving voltage may be applied to the DUT 10 through the power terminal 14, and a ground voltage may be applied to the DUT 10 through the ground terminal 16. According to the specification of the DUT 10, the driving voltage may be referred to as VDD, VDD1, VDD2, etc., and the ground voltage may be referred to as VSS, VSS1, VSS2, GND, etc. Data such as, for example, a command, an address, or input/output data may be input to the DUT 10 through the data terminal 18 or may be output from the DUT 10 through the data terminal 18. In the exemplary embodiment illustrated in FIG. 1 the DUT 10 includes four power terminals 14, four ground terminals 16, and fourteen data terminals 18. However, exemplary embodiments of the inventive concept are not limited thereto.

The terminals 12 may have various shapes depending on the shape of the DUT 10. For example, in a case in which the DUT 10 is in the form of a semiconductor die, the terminals 12 may be in the shape of a contact pad. In a case in which the DUT 10 is in the shape of a semiconductor package, the terminals 12 may be in the form of a ball, a pad, a lead, a pin, etc., depending on the type of package. For example, in a case in which the DUT 10 is a FBGA semiconductor, the ball-shaped terminals of the FBGA semiconductor may be connected (or accessed) to the sockets of the test interface board 100.

In exemplary embodiments, the test interface board 100 includes a substrate 110 and a controller 120. The substrate 110 includes a connection area 130 in which the DUT 10 is connected. The pads 132 corresponding to the terminals 12 of the DUT 10 are disposed in the connection area 130. In exemplary embodiments, the pads 132 include power pads 134, ground pads 136, and data pads 138. The type, quantity, and position of the pads 132 may vary depending on the corresponding terminals 12 of the DUT 10.

In exemplary embodiments, the DUT 10 may be disposed directly on the connection area 130 or adjacent to the connection area 130, and the power terminals 14, the ground terminals 16 and the data terminals 18 of the DUT 10 may be electrically connected to the corresponding power pads 134, the corresponding ground pads 136, and the corresponding data pads 138 of the test interface board 100, respectively. Alternatively, in exemplary embodiments, the DUT 10 may be loaded onto a socket, as described above, so as to be mounted in the connection area 130, and the power terminals 14, the ground terminals 16 and the data terminals 18 of the DUT 10 may be electrically connected to the corresponding power pads 134, the corresponding ground pads 136, and the corresponding data pads 138 of the test interface board 100 through pads included in the socket, respectively.

The exemplary embodiment illustrated in FIG. 1 shows that the test interface board 100 is used to test one DUT 10. However, exemplary embodiments of the inventive concept are not limited thereto. For example, in exemplary embodiments, the test interface board 100 may be connected to a plurality of DUTs 10.

The substrate 110 may include at least one printed circuit board. For example, the substrate 110 may include a multilayer printed circuit board including a plurality of conductive layers, each of which is interposed between a plurality of insulating layers. Some of a plurality of conductive layers may include a power plane 112, and others of the plurality of conductive layers may include a ground plane 114.

In exemplary embodiments, the power plane 112 is connected to the power pads 134, and the ground plane 114 is connected to the ground pads 136. In exemplary embodiments, the power plane 112 is connected to the power pads 134 by using insulating layers disposed between the power plane 112 and the power pads 134 and a via contact plug penetrating the conductive layer(s). In exemplary embodiments, the ground plane 114 is connected to the ground pads 136 by using insulating layers disposed between the ground plane 114 and the ground pads 136 and a via contact plug penetrating the conductive layer(s).

In exemplary embodiments, the controller 120 supplies a driving voltage and a ground voltage to the DUT 10 through the power plane 112 and the ground plane 114. The controller 120 supplies the driving voltage to the power plane 112, and supplies the ground voltage to the ground plane 114. For example, the controller 120 may maintain the potential difference between the power plane 112 and the ground plane 114 at the level of the driving voltage by using an active element (e.g., a transistor, an operational amplifier, etc.). In exemplary embodiments, the test interface board 100 does not include the controller 120. For example, the driving voltage and the ground voltage supplied from the ATE may be supplied to the power plane 112 and the ground plane 114 without passing through the controller 120.

In exemplary embodiments, the test interface board 100 further includes a connector 140 and wirings 152 connected to the connector 140. The ATE that generates a test sequence for testing the DUT 10 may be connected to the connector 140. One integrated cable may be connected to the connector 140, or a plurality of cables may be connected to the connector 140. However, in exemplary embodiments, the test interface board 100 may be directly installed in a test header without the connector 140, and the test header may be electrically connected to a test device.

In exemplary embodiments, the wirings 152 include a power wiring 154, a ground wiring 156, and a data wiring 158. The power wiring 154 and the ground wiring 156 may electrically connect the connector 140 to the controller 120. The data wiring 158 may connect the connector 140 to the data pads 138. According to an exemplary embodiment, the data wiring 158 is not connected to all of the data pads 138, and may be electrically connected to only the data pads 138 used to test the DUT 10.

In the exemplary embodiment illustrated in FIG. 1, the wirings 152 are disposed on the upper surface of the substrate 110. However, exemplary embodiments of the inventive concept are not limited thereto. For example, the wirings 152 may be implemented by using at least one conductive layer selected from among the conductive layers included in the substrate 110. The wirings 152 may be electrically connected to the controller 120, which is disposed on the upper surface of the substrate 110, by using a via contact plug and the data pads 138.

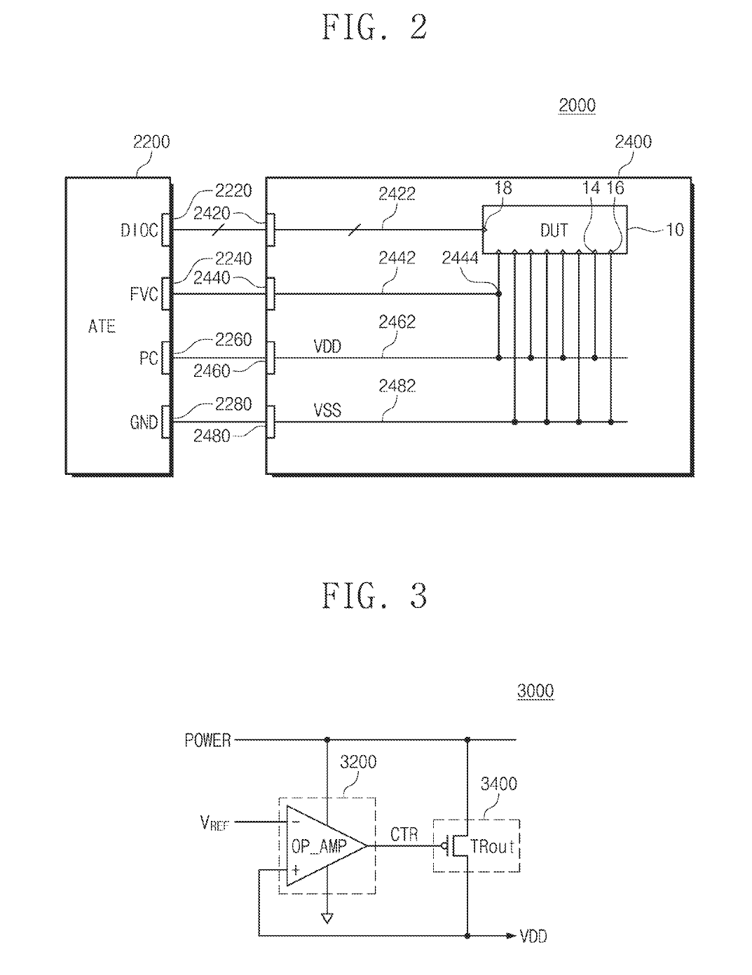

FIG. 2 illustrates a conceptual diagram of a test system, according to an exemplary embodiment of the inventive concept.

In exemplary embodiments, a test system 2000 includes the ATE 2200, which tests the DUT 10, and a test interface board 2400 that connects the DUT 10 to the ATE 2200.

The DUT 10 may include the power terminal 14, the ground terminal 16, and the data terminal 18. Since the DUT 10 is described with reference to FIG. 1, a further detailed description is omitted herein.

In exemplary embodiments, the test interface board 2400 includes a data input/output terminal 2420 for connection with the ATE 2200, a feedback voltage output terminal 2440, a power input terminal 2460, and a ground input terminal 2480. In exemplary embodiments, the data input/output terminal 2420, the feedback voltage output terminal 2440, the power input terminal 2460, and the ground input terminal 2480 constitute the connector 140 of FIG. 1.

In exemplary embodiments, the test interface board 2400 includes a power plane 2462 that provides a driving voltage to the power terminal 14 of the DUT 10, and a ground plane 2482 that provides a ground voltage to the DUT 10. The power plane 2462 and the ground plane 2482 may correspond to the power plane 112 and the ground plane 114 in FIG. 1, respectively, and is displayed as a wiring in FIG. 2.

The ATE 2200 may output a test sequence for testing the DUT 10. In exemplary embodiments, the ATE 2200 includes a data input/output channel (DIOC) 2220, a feedback voltage channel (FVC) 2240, a power output channel (PC) 2260, and a ground (GND) 2280. The ATE 2200 may further include a memory that stores instructions, and a processor that executes the instructions, for example, to perform a test operation. Herein, the terms “ATE” and “ATE circuit” may be used interchangeably.

The power output channel 2260 may supply a voltage to the test interface board 2400 through the power input terminal 2460. The supplied voltage may be applied through the power plane 2462 as the driving voltage of the DUT 10. The power output channel 2260 may supply a power with a current amount less than the maximum allowable current value. The ATE 2200 may include a power supply that supplies a voltage through the power output channel 2260.

The ground 2280 may be connected to the ground plane 2482 through the ground input terminal 2480 of the test interface board 2400. Since the ground plane 2482 is connected to the ground terminal 16 of the DUT 10, the ATE 2200, the test interface board 2400, and the DUT 10 may have the same ground potential.

In exemplary embodiments, the feedback voltage channel 2240 is connected to the feedback voltage output terminal 2440 of the test interface board 2400. The test interface board 2400 measures the driving voltage applied to the DUT 10, and transmits the measured driving voltage to the ATE 2200 through the feedback voltage output terminal 2440. The driving voltage transmitted to the ATE 2200 used as a feedback voltage for adjusting the voltage output by the power output channel 2260.

The driving voltage applied to the DUT 10 may be different from a voltage received through the power input terminal 2460. This may be the case because the voltage drop by resistance occurs while the voltage received through the power input terminal 2460 is transmitted to the DUT 10. The resistance may include, for example, resistance by a wiring, a plane, etc. in the test interface board 2400. For example, the resistance may include the contact resistance of the socket. Accordingly, the test interface board 2400 may measure the driving voltage actually applied to the DUT 10, and may transmit the measured driving voltage to the ATE 2200.

In exemplary embodiments, the ATE 2200 adjusts the voltage output by the power output channel 2260 based on the driving voltage received from the test interface board 2400. In exemplary embodiments, the ATE 2200 adjusts the level of the voltage output by the power output channel 2260 such that the driving voltage applied to the DUT 10 is the same as a reference voltage. The reference voltage refers to the driving voltage that should be applied to the DUT 10 for the purpose of accurately testing the electrical characteristics of the DUT 10. For example, in exemplary embodiments, if a voltage other than the reference voltage is applied to the DUT 10 as the driving voltage, the electrical characteristics of the DUT 10 may not be accurately measured. For example, in a case in which the DUT 10 is a Low Power DDR (LPDDR), the reference voltage may be about 1.1 V. Hereinafter, the driving voltage measured to adjust a voltage output by the ATE 2200 is referred to as a feedback voltage.

Hereinafter, a location at which the feedback voltage is measured is referred to as a sensing point. In exemplary embodiments, the feedback voltage measured at the sensing point is transmitted to the ATE 2200 through a sensing wiring 2442. For example, the sensing point may be a cross point 2444 of a wiring that supplies the driving voltage from the power plane 2462 to the DUT 10 and the sensing wiring 2442 (see FIG. 2). In exemplary embodiments, the sensing wiring 2442 is a wiring connection between the sensing point and the feedback voltage output terminal 2440.

In exemplary embodiments, the data input/output channel 2220 is connected to the data terminal 18 of the DUT 10 through the data input/output terminal 2420 of the test interface board 2400. The ATE 2200 may output a test sequence for testing the DUT 10 through the data input/output channel 2220, and may receive data output from the DUT 10. The wiring 2422 may correspond to the data wiring 158 of FIG. 1, and functions as a path through which the data moves. For example, in a case in which the DUT 10 is a DRAM, the ATE 2200 may write a reference data pattern with respect to all memory cells, and may read the written reference data pattern.

FIG. 3 is circuit diagram of a voltage controller, according to an exemplary embodiment of the inventive concept.

In exemplary embodiments, the ATE 2200 of FIG. 2 includes a voltage controller 3000 that adjusts the level of the voltage output by the power output channel 2260 based on the received feedback voltage.

In exemplary embodiments, the voltage controller 3000 is a device that adjusts a voltage VDD supplied to a test interface board (e.g., the test interface board 2400 of FIG. 2) based on a reference voltage V_{REF}. As described above, the reference voltage V_{REF} is the driving voltage that should be applied to the DUT 10 for the purpose of accurately testing the electrical characteristics of the DUT 10. In exemplary embodiments, the voltage controller 3000 is a device different from the controller 120 of the test interface board 100 described with reference to FIG. 1. For example, in exemplary embodiments, the voltage controller 3000 is a device placed inside the ATE 2200.

In exemplary embodiments, the voltage controller 3000 includes active elements such as, for example, an operational amplifier (OP_AMP) 3200 and a transistor (Trout) 3400.

In exemplary embodiments, the operational amplifier 3200 includes an inverting terminal (−) to which the reference voltage V_{REF} is applied, and a non-inverting terminal (+) to which the driving voltage VDD is applied. In exemplary embodiments, the driving voltage VDD applied to the non-inverting terminal (+) is the feedback voltage described above with reference to FIG. 2. The operational amplifier 3200 may further include an output terminal that outputs a control signal CTR.

In exemplary embodiments, the operational amplifier 3200 outputs the control signal CTR through the output terminal. According to exemplary embodiments, in a case in which the driving voltage VDD is greater than the reference voltage V_{REF}, the voltage level of the control signal CTR increases, and in a case in which the driving voltage VDD is smaller than the reference voltage V_{REF}, the voltage level of the control signal CTR decreases.

The transistor 3400 may be, for example, a P-channel metal-oxide semiconductor field effect transistor (MOSFET) including a control terminal to which the control signal CTR is applied, a first terminal connected to power POWER, and a second terminal for outputting the driving voltage VDD. However, the transistor 3400 is not limited to a P-channel MOSFET. For example, in exemplary embodiments, an N-channel MOSFET or a bipolar junction transistor (BJT) may be used by changing the circuit configuration of the voltage controller 3000.

According to exemplary embodiments, when the voltage level of the control signal CTR increases, the amount of a current flowing from the first terminal of the transistor TRout to the second terminal decreases, and when the voltage level of the control signal CTR decreases, the amount of a current flowing from the first terminal of the transistor TRout to the second terminal increases.

In exemplary embodiments, in a case in which the driving voltage VDD is greater than the reference voltage V_{REF}, since the voltage level of the control signal CTR increases, the amount of a current flowing from the first terminal of the transistor TRout 3400 to the second terminal of the transistor TRout 3400 decreases. As a result, since the amount of a current supplied to the test interface board (e.g., the test interface board 2400 of FIG. 2) decreases, the level of the driving voltage VDD decreases.

In exemplary embodiments, in a case in which the driving voltage VDD is smaller than the reference voltage V_{REF}, since the voltage level of the control signal CTR decreases, the amount of a current flowing from the first terminal of the transistor TRout 3400 to the second terminal of the transistor TRout 3400 increases. As a result, since the amount of a current supplied to the test interface board (e.g., the test interface board 2400 of FIG. 2) increases, the level of the driving voltage VDD increases.

Accordingly, in exemplary embodiments, the voltage controller 3000 causes the driving voltage applied to the DUT 10 to be the reference voltage by adjusting the voltage output by using the operational amplifier 3200 and the transistor 3400.

FIG. 4 illustrates a conceptual diagram of a test system, according to an exemplary embodiment of the inventive concept.

The test system 4000 of FIG. 4 is a more detailed illustration of the test system 2000 of FIG. 2. Thus, the same reference numerals may be used, and a further description of elements previously described with reference to FIG. 2 may be omitted herein.

In exemplary embodiments, a DUT 4200 is in the form of an integrated package in which a plurality of homogeneous or heterogeneous semiconductor packages are integrated into one package. For example, the DUT 4200 may be a FBGA semiconductor. The DUT 4200 may include ball-shaped power terminals, ground terminals, and data terminals. For convenience of description, it is assumed that all of the illustrated terminals 4220 are power terminals. However, exemplary embodiments are not limited thereto. In addition, for convenience description, all of the terminals 4220 are illustrated as having a ball shape. However, exemplary embodiments are not limited thereto.

In exemplary embodiments, the DUT 4200 is connected to the test interface board 2400 through a socket 4400. The socket 4400 is an element that enables an interface operation between the test interface board 2400 and the DUT 4200. For example, the socket 4400 may be comprised of silicone rubber and conductive particles. The conductive particles of the socket 4400 may receive an electrical signal from the DUT 4200.

The DUT 4200 may be loaded onto the socket 4400. When loaded, the pads included in the socket 4400 are connected to the terminals 4220 of the DUT 4200.

In exemplary embodiments, a sensing point 4444 at which a feedback voltage is measured is disposed between the power plane 2462 and the socket 4400. The feedback voltage measured at the sensing point 4444 is transmitted to the feedback voltage output terminal 2440 by the sensing wiring 2442. Thus, in exemplary embodiments, the test interface board 2400 measures a second voltage (e.g., the feedback voltage) applied to the DUT 4200 based on a first voltage (e.g., the driving voltage VDD) supplied from the ATE 2200, and the sensing wire 2442 transmits the measured second voltage to the ATE 2200. The second voltage (e.g., the feedback voltage) is a voltage to which the first voltage (e.g., the driving voltage VDD) is dropped by a resistance (e.g., a contact resistance of the socket 4400).

In exemplary embodiments, the socket 4400 is a resistive element having a finite lifetime. For example, the socket 4400 may have contact resistance. Accordingly, while the driving voltage output from the power plane 2462 passes through the socket 4400, a voltage drop (e.g., IR Drop) may occur. In this case, the driving voltage applied to the DUT 4200 may be less than the feedback voltage measured at the sensing point 4444. Accordingly, if the sensing point 4444 is placed between the power plane 2462 and the socket 4400, a difference between the measured feedback voltage and the driving voltage actually applied to the DUT 4200 may occur and be measured.

FIG. 5 illustrates a conceptual diagram of a test system, according to an exemplary embodiment of the inventive concept.

The test system 5000 of FIG. 5 is different from the test system 4000 of FIG. 4 in that a sensing point 5444 for measuring the feedback voltage is disposed inside the interior of the DUT 4200. Since the sensing point 5444 is in the interior of the DUT 4200, the driving voltage applied to the DUT 4200 may be measured accurately. For convenience of description, the same reference numerals may be used to denote elements previously described, and a further description of elements previously described may be omitted herein.

The sensing wiring 2442 of the test interface board 2400 is connected to a sensing point 5444 located inside the interior of the DUT 4200 (e.g., located at an interior location of the DUT 4200). Thus, the feedback voltage, to which the voltage drop of the driving voltage by the socket 4400 is applied, may be measured. Accordingly, the ATE 2200 may adjust the level of the output voltage based on the accurate feedback voltage.

In exemplary embodiments, the sensing point is located at an interior location of a DUT such that the sensing point is embedded within (e.g., completely embedded within) the DUT. For example, in exemplary embodiments, the sensing point is entirely surrounded by the surfaces of the DUT. For example, in exemplary embodiments, the sensing point is entirely covered by upper and lower surfaces of the DUT and entirely covered by side surfaces of the DUT.

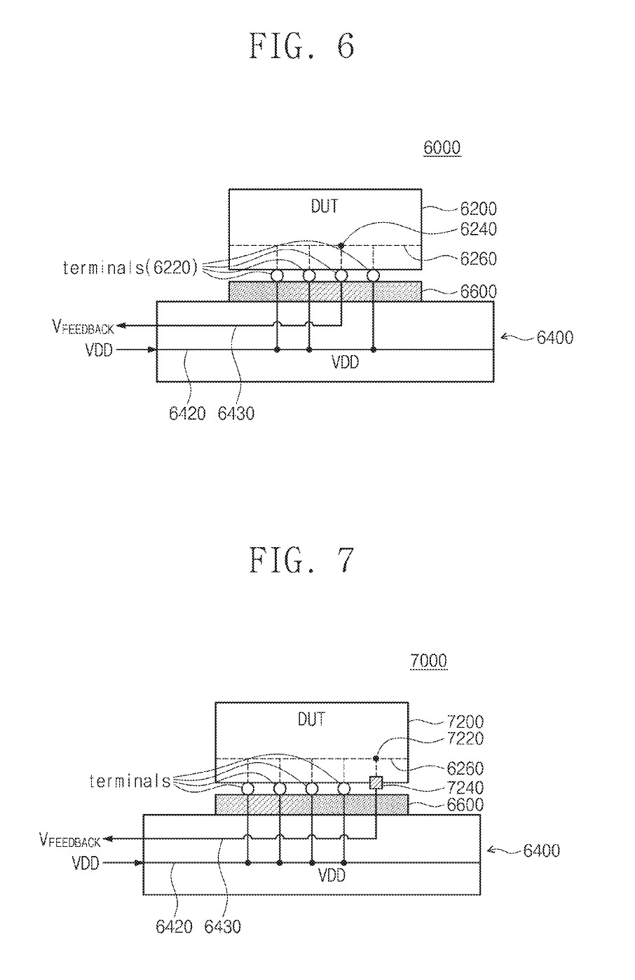

FIG. 6 illustrates a front view of a test system, according to an exemplary embodiment of the inventive concept.

The test system 6000 of FIG. 6 represents a part of the test system 5000 of FIG. 5.

In exemplary embodiments, a test interface board 6400 includes a socket 6600 for connection with a DUT 6200. The driving voltage output from a voltage plane 6420 is applied to the DUT 6200 through the socket 6600. In exemplary embodiments, the DUT 6200 is in the form of a semiconductor package.

The pads included in the socket 6600 may be electrically connected to terminals 6220 of the DUT 6200. For example, the terminals 6220 of the DUT 6200 may have a ball shape. As described above, the terminals 6220 of the DUT 6200 may include at least one power terminal, at least one ground terminal, and at least one data terminal. For convenience of description, it is assumed that the four illustrated terminals 6220 are power terminals. However, exemplary embodiments are not limited thereto.

In exemplary embodiments, a sensing point 6240 for measuring the driving voltage applied to the DUT 6200 is placed inside the interior of the DUT 6200. For example, in exemplary embodiments, the sensing point 6240 is placed on a channel 6260 for merging driving voltages respectively received from each of the plurality of power terminals 6220. In exemplary embodiments, the channel 6260 may be referred to as a VDD Net or a Power Net, and refers to a channel having a power attribute.

In the exemplary embodiment illustrated in FIG. 6, a sensing wiring 6430 is connected to the sensing point 6240 through one terminal of the four the terminals 6220. However, exemplary embodiments are not limited thereto.

FIG. 7 illustrates a front view of a test system, according to an exemplary embodiment of the inventive concept.

The test system 7000 is different from the test system 6000 of FIG. 6 in that a DUT 7200 includes a separate sensing terminal 7240 for connecting with the sensing wiring 6430. In this case, the sensing wiring 6430 is connected to a sensing point 7220 through the sensing terminal 7240. For convenience of description, the same reference numerals may be used to denote elements previously described, and a further description of elements previously described may be omitted herein. In exemplary embodiments, the sensing terminal 7240 is disposed on the surface of the DUT 7200. The sensing terminal 7240 may be in the form of a pad. However, exemplary embodiments are not limited thereto.

As described above, the DUT may be a semiconductor device. Accordingly, exemplary embodiments provide a method of manufacturing a semiconductor device in which the semiconductor device is tested using the test system according to the exemplary embodiments described herein. For example, in exemplary embodiments, a method of manufacturing a semiconductor device includes forming the semiconductor device as part of a wafer or a package, and testing the semiconductor device. As described herein, in exemplary embodiments, the testing of the semiconductor device is performed using an automatic test equipment configured to test the semiconductor device, and a test interface board configured to measure a second voltage applied to the semiconductor device based on a first voltage supplied from the automatic test equipment. The test interface board includes a sensing wiring configured to transmit the measured second voltage to the automatic test equipment, and the second voltage is measured at an interior location of the semiconductor device.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

What is claimed is:

1. A test system, comprising:
an automatic test equipment configured to test a device under test; and
a test interface board configured to measure a second voltage applied to the device under test based on a first voltage supplied from the automatic test equipment,
wherein the test interface board comprises a sensing wiring configured to transmit the measured second voltage to the automatic test equipment,
wherein the second voltage is measured at an interior location of the device under test.

2. The test system of claim 1, wherein the test interface board further comprises:
a feedback voltage output terminal configured to transmit the measured second voltage to the automatic test equipment,
wherein the sensing wiring is disposed between and connects a sensing point at the interior location of the device under test and the feedback voltage output terminal,
wherein the sensing point corresponds to the interior location at which the second voltage is measured.

3. The test system of claim 2, wherein the device under test comprises:
a first power terminal;
a second power terminal; and
a channel configured to merge a voltage received from the first power terminal and a voltage received from the second power terminal,
wherein the sensing point is disposed on the channel, and the sensing wiring is connected to the sensing point through a third power terminal of the device under test.

4. The test system of claim 1, wherein the automatic test equipment is configured to supply the first voltage to the test interface board, and the second voltage is a voltage to which the first voltage is dropped by a resistance.

5. The test system of claim 4, wherein the test interface board further comprises:
a socket configured to connect to the device under test, wherein the resistance is a contact resistance of the socket.

6. The test system of claim 5, wherein the device under test is a fine ball grid array (FBGA) semiconductor comprising a plurality of ball-shaped terminals configured to connect to the socket.

7. The test system of claim 5, wherein the socket comprises a conductive particle, and the conductive particle receives an electrical signal from the device under test.

8. The test system of claim 4, wherein the first voltage is supplied to the test interface board through a power output channel of the automatic test equipment.

9. The test system of claim 4, wherein the automatic test equipment is configured to adjust the first voltage based on the measured second voltage, and supply the adjusted first voltage to the test interface board.

10. The test system of claim 9, wherein the adjusted first voltage is a reference voltage, and the reference voltage is a driving voltage applied to the device under test to test an electrical characteristic of the device under test.

11. The test system of claim 1, wherein the test interface board further comprises:
a power plane electrically connected to a power terminal of the device under test,
wherein the power plane applies the second voltage to the device under test.

12. The test system of claim 1, wherein the test interface board further comprises:
a ground plane electrically connected to a ground terminal of the device under test,
wherein the ground plane applies a ground voltage to the device under test.

13. The test system of claim 1, wherein the test interface board further comprises:
a data wiring connected to a data input/output terminal of the device under test,
wherein the data wiring transfers data input signals and data output signals between the test interface board and the automatic test equipment.

14. A test interface board connected to a device under test, comprising:
a power plane that receives a first voltage from an automatic test equipment; and
a sensing wiring that measures a second voltage applied to the device under test through the power plane,
wherein the sensing wiring is connected to an interior location of the device under test.

15. The test interface board of claim 14, wherein the sensing wiring connects a sensing point disposed at the interior location of the device under test to a channel, the second voltage is measured at the sensing point, and the test interface board transmits the measured second voltage to the automatic test equipment through the channel.

16. The test interface board of claim 14, wherein the second voltage is a voltage to which the first voltage is dropped by a resistance.

17. The test interface board of claim 16, further comprising:
a socket that connects to the device under test, wherein the resistance is a contact resistance of the socket.

18. The test interface board of claim 17, wherein the device under test comprises a plurality of ball-shaped terminals, and the socket is connected to the ball-shaped terminals.

19. The test interface board of claim 17, wherein the socket comprises a conductive particle, and the conductive particle receives an electrical signal from the device under test.

20. A semiconductor device, comprising:
a voltage terminal that receives a driving voltage from a test interface board,
wherein the semiconductor device is connected to the test interface board, and the test interface board measures an electrical characteristic of the semiconductor device;
a ground terminal that receives a ground voltage from the test interface board;
a data terminal that receives data from the test interface board; and
a sensing terminal that measures the driving voltage,
wherein the sensing terminal is disposed on a surface of the semiconductor device and is connected to a sensing wiring of the test interface board,
wherein the sensing wiring is connected to a sensing point disposed at an interior location of the semiconductor device, and the driving voltage is measured at the sensing point.

21. A method of manufacturing a semiconductor device, comprising:
forming the semiconductor device as part of a wafer or a package; and
testing the semiconductor device, wherein
the testing of the semiconductor device is performed using an automatic test equipment configured to test the semiconductor device, and a test interface board configured to measure a second voltage applied to the semiconductor device based on a first voltage supplied from the automatic test equipment,
wherein the test interface board comprises a sensing wiring configured to transmit the measured second voltage to the automatic test equipment, and the second voltage is measured at an interior location of the semiconductor device.

22. The method of claim 21, wherein the testing of the semiconductor device comprises:
adjusting, by the automatic test equipment, the first voltage based on the measured second voltage; and
supplying, by the automatic test equipment, the adjusted first voltage to the test interface board.

23. The method of claim 22, wherein the adjusted first voltage is a reference voltage, and the reference voltage is a driving voltage applied to the semiconductor device to test an electrical characteristic of the semiconductor device.
